(19) United States
(12) Patent Application Publication
(10) Pub. No.: US 2015/0206596 A1
(43) Pub. Date: Jul. 23, 2015

(54) MANAGING A RING BUFFER SHARED BY MULTIPLE PROCESSING ENGINES

(71) Applicant: NVIDIA CORPORATION, Santa Clara, CA (US)

(72) Inventor: Richard Gary John BAVERSTOCK, Gilroy, CA (US)

(73) Assignee: NVIDIA CORPORATION, Santa Clara, CA (US)

(21) Appl. No.: 14/160,344

(22) Filed: Jan. 21, 2014

(51) Int. Cl. G11C 19/00; H04N 19/436; H04N 19/423

(52) U.S. Cl. CPC G11C 19/00; H04N 19/423; H04N 19/436

(57) ABSTRACT

A technique for managing data processed by multiple processing engines comprises storing a first data block associated with a first processing engine in a first portion of a ring buffer memory, subsequent to storing the first data block, storing a second data block associated with a second processing engine in a second portion of the ring buffer memory, and receiving a second process complete signal from the second processing engine while waiting for a first process complete signal from the first processing engine. The technique further comprises receiving the first process complete signal from the first processing engine once the first processing engine completes processing of the first data block, and, upon receiving the first process complete signal, indicating that the first portion of the ring buffer memory is available for storing data other than the first data block.

### FIELD OF THE INVENTION

Embodiments of the present invention relate generally to computing systems and, more specifically, to managing a ring buffer shared by multiple processing engines.

### DESCRIPTION OF THE RELATED ART

In many areas of modern computing, high-speed processing of data is critical for achieving targeted performance, for example in video streaming, cloud-based gaming, and the like. To facilitate data processing at acceptable rates for such applications, some stages of processing can be performed using parallel processing techniques. For example, in video decoding, portions of the stage known as motion compensation can be performed in parallel using multiple processing engines that are sometimes referred to as interpolators. Generally, in such a parallel process, blocks of data related to different pixels in a video frame are fetched from physical memory and stored in a buffer that is accessed by multiple interpolators. The data blocks are then processed in parallel by the interpolators, and the processed data blocks are used in subsequent stages of decoding.

Various schemes for implementing such parallel processing may be used to minimize processing latency and interpolator idle time. For example, storage of data blocks in a ping-pong buffer prior to processing can reduce the time that interpolators are idle while data are fetched from physical memory. This is because the ping-pong buffer includes two sequentially filled buffers, i.e., a “ping” buffer and a “pong” buffer, and this allows interpolators to process data stored in one of the buffers during the time that the other buffer is loaded with additional data blocks.

However, in schemes using a ping-pong buffer, there can still be significant interpolator idle time. For instance, due to the latency associated with retrieving data from physical memory, interpolators can often complete processing of data in the ping buffer before the pong buffer has been loaded, and therefore remain idle until loading of the pong buffer is complete. Furthermore, one or more of the multiple interpolators are typically idle whenever there are more interpolators than remaining data blocks to be processed in a ping or pong buffer. For example, when the ping buffer stores four data blocks for processing by three interpolators, all three interpolators can process the first three data blocks in parallel, but two of the three interpolators are idle while the fourth data block in the ping buffer is being processed.

There are also sources of unwanted processing latency in schemes using a ping-pong buffer. For example, data blocks that have been processed by interpolators may remain in either the ping buffer or the pong buffer for a significant length of time rather than being immediately available for use in subsequent stages of decoding. This is because the ping (or pong) buffer retains processed data blocks until all data blocks in the ping (or pong) buffer are processed before the processed data blocks are released, thereby preventing out-of-order completion of data by the interpolators. Otherwise, out-of-order completion of data block processing results in out-of-order release of the processed data blocks. In other words, if processed data block are released as soon as processing is completed thereon, whenever an interpolator completes the processing of a data block loaded in the ping buffer before a previously loaded data block, out-of-order completion of the data blocks will result, which is highly undesirable.

As the foregoing illustrates, what is needed in the art is a more effective way for multiple processing engines to process data stored in buffer memory.

### SUMMARY OF THE INVENTION

One embodiment of the present invention sets forth a method for managing data processed by multiple processing engines. The method includes storing a first data block associated with a first processing engine in a first portion of a ring buffer memory, and, subsequent to storing the first data block, storing a second data block associated with a second processing engine in a second portion of the ring buffer memory. The method also includes receiving a second process complete signal from the second processing engine, while waiting for a first process complete signal from the first processing engine, receiving the first process complete signal from the first processing engine once the first processing engine completes processing of the first data block, and, upon receiving the first process complete signal, indicating that the first portion of the ring buffer memory is available for storing data other than the first data block.

One advantage of the disclosed embodiments is that latency incurred in video decoding is reduced, since an interpolator or other processing engine can begin processing the next available data block in a ring buffer without causing out-of-order completion of data block processing. An additional advantage is that data blocks processed by an interpolator can be released from a buffer for use in subsequent processes without being held until all other data blocks in the buffer have been processed.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a block diagram illustrating a computer system configured to implement one or more aspects of the present invention.

FIG. 2 is a block diagram illustrating the video decoding unit of FIG. 1, according to an embodiment of the present invention.

FIG. 3 is a block diagram illustrating the motion compensation module of FIG. 2, according to an embodiment of the present invention.

FIG. 4 is a schematic diagram illustrating the ring buffer of FIG. 3, according to an embodiment of the present invention.

FIG. 5 is a block diagram illustrating elements of the motion compensation unit of FIG. 2 configured to implement a reordering scheme for the release of data stored in a ring buffer, according to an embodiment of the present invention.

FIG. 6 is a block diagram illustrating elements of the motion compensation unit of FIG. 2, in which a bilinear data block may be processed, according to an embodiment of the present invention.

FIG. 7 sets forth a flowchart of method steps for managing data processed by multiple processing engines and stored in a common buffer memory, according to one embodiment of the present invention.

FIG. 8 sets forth a flowchart of method steps for a process flow of data processed by multiple processing engines, according to one embodiment of the present invention.

For clarity, identical reference numbers have been used, where applicable, to designate identical elements that are common between figures. It is contemplated that features of one embodiment may be incorporated in other embodiments without further recitation.

### DETAILED DESCRIPTION

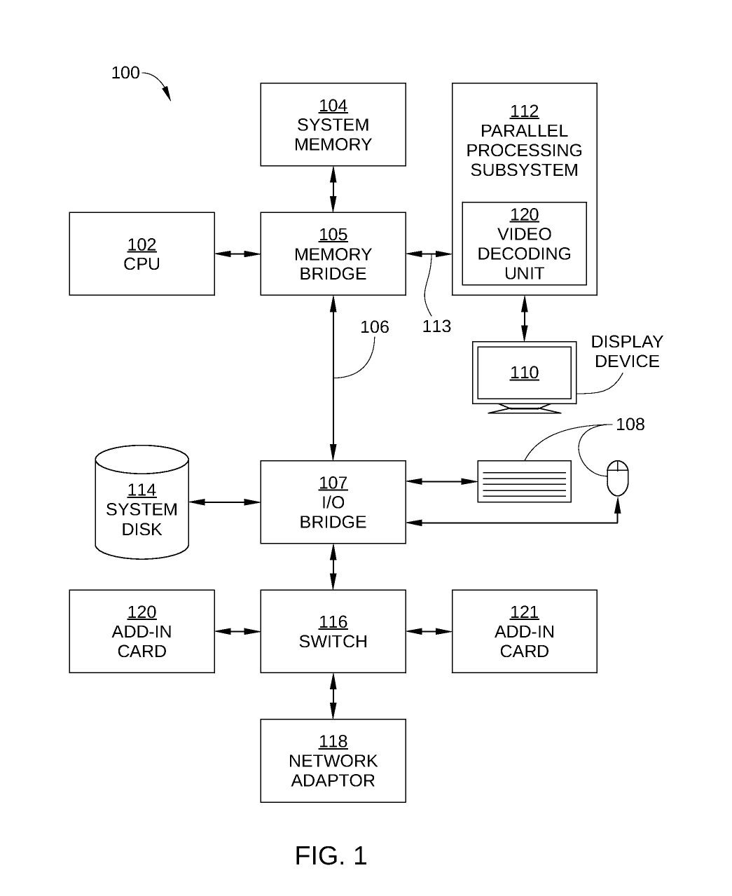

FIG. 1 is a block diagram illustrating a computer system 100 configured to implement one or more aspects of the present invention. As shown, computer system 100 includes, without limitation, a central processing unit (CPU) 102 and a system memory 104 coupled to a parallel processing subsystem 112 via a memory bridge 105 and a communication path 113. Memory bridge 105 is further coupled to an I/O (input/output) bridge 107 via a communication path 106, and I/O bridge 107 is, in turn, coupled to a switch 116.

In operation, I/O bridge 107 is configured to receive user input information from input devices 108, such as a keyboard or a mouse, and forward the input information to CPU 102 for processing via communication path 106 and memory bridge 105. Switch 116 is configured to provide connections between I/O bridge 107 and other components of the computer system 100, such as a network adapter 118 and various add-in cards 120 and 121.

As also shown, I/O bridge 107 is coupled to a system disk 114 that may be configured to store content and applications and data for use by CPU 102 and parallel processing subsystem 112. As a general matter, system disk 114 provides non-volatile storage for applications and data and may include fixed or removable hard disk drives, flash memory devices, and CD-ROM (compact disc read-only-memory), DVD-ROM (digital versatile disc-ROM), Blu-ray, HD-DVD (high definition DVD), or other magnetic, optical, or solid state storage devices. Finally, although not explicitly shown, other components, such as universal serial bus or other port connections, compact disc drives, digital versatile disc drives, film recording devices, and the like, may be connected to I/O bridge 107 as well.

In various embodiments, memory bridge 105 may be a Northbridge chip, and I/O bridge 107 may be a Southbrige chip. In addition, communication paths 106 and 113, as well as other communication paths within computer system 100, may be implemented using any technically suitable protocols, including, without limitation, AGP (Accelerated Graphics Port), HyperTransport, or any other bus or point-to-point communication protocol known in the art.

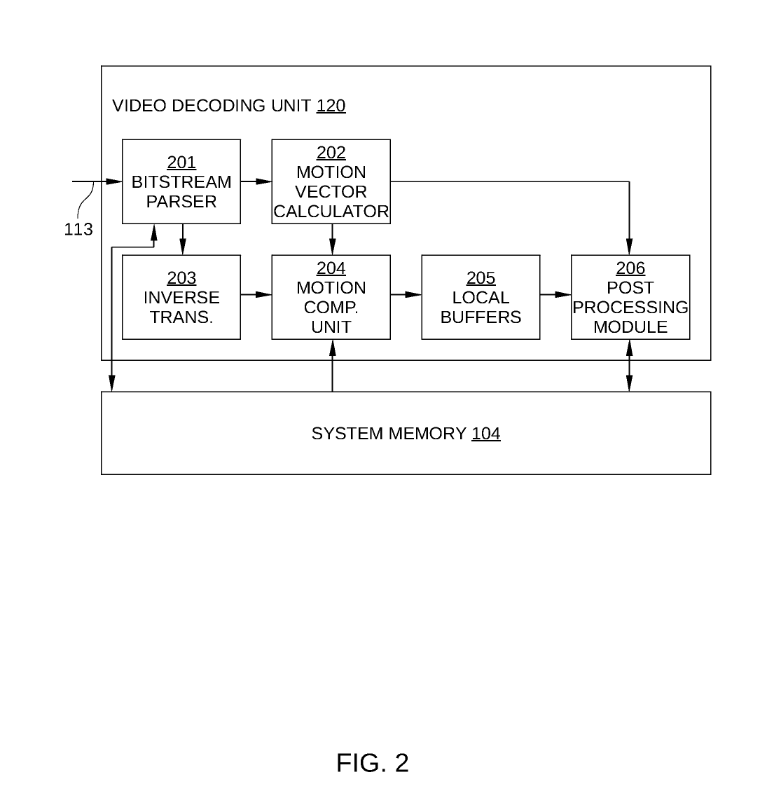

In some embodiments, parallel processing subsystem 112 comprises a graphics subsystem that delivers pixels to a display device 110 that may be any conventional cathode ray tube, liquid crystal display, light-emitting diode display, or the like. In such embodiments, the parallel processing subsystem 112 incorporates circuitry optimized for graphics and video processing, including, for example, video output circuitry and/or a video decode unit 120, which is described below in conjunction with FIG. 2. Video decode unit 120 may be incorporated across one or more parallel processing units (PPUs) included within parallel processing subsystem 112, and one or more of these PPUs may be configured as a graphics processing unit (GPU). In the embodiment shown in FIG. 1, video decode unit 120 resides within parallel processing subsystem 112. In other embodiments, video decode unit 120 may reside in a device or subsystem that is separate from parallel processing subsystem 112, such as memory add-in cards 120 or 121.

In other embodiments, the parallel processing subsystem 112 incorporates circuitry optimized for general purpose and/or compute processing. Again, such circuitry may be incorporated across one or more PPUs included within parallel processing subsystem 112 that are configured to perform such general purpose and/or compute operations. In yet other embodiments, the one or more PPUs included within parallel processing subsystem 112 may be configured to perform graphics processing, general purpose processing, and compute processing operations. System memory 104 includes at least one device driver 103 configured to manage the processing operations of the one or more PPUs within parallel processing subsystem 112. In various embodiments, parallel processing subsystem 112 may be integrated with one or more of the other elements of FIG. 1 to form a single system. For example, parallel processing subsystem 112 may be integrated with CPU 102 and other connection circuitry on a single chip to form a system on chip (SoC).

It will be appreciated that the system shown herein is illustrative and that variations and modifications are possible. The connection topology, including the number and arrangement of bridges, the number of CPUs 102, and the number of parallel processing subsystems 112, may be modified as desired. For example, in some embodiments, system memory 104 is connected to CPU 102 directly rather than through memory bridge 105, and other devices communicate with system memory 104 via memory bridge 105 and CPU 102. In other alternative topologies, parallel processing subsystem 112 may be connected to I/O bridge 107 or directly to CPU 102, rather than to memory bridge 105. In still other embodiments, I/O bridge 107 and memory bridge 105 may be integrated into a single chip instead of existing as one or more discrete devices. Lastly, in certain embodiments, one or more components shown in FIG. 1 may not be present. For example, switch 116 may be eliminated, and network adapter 118 and add-in cards 120 and 121 connect directly to I/O bridge 107.

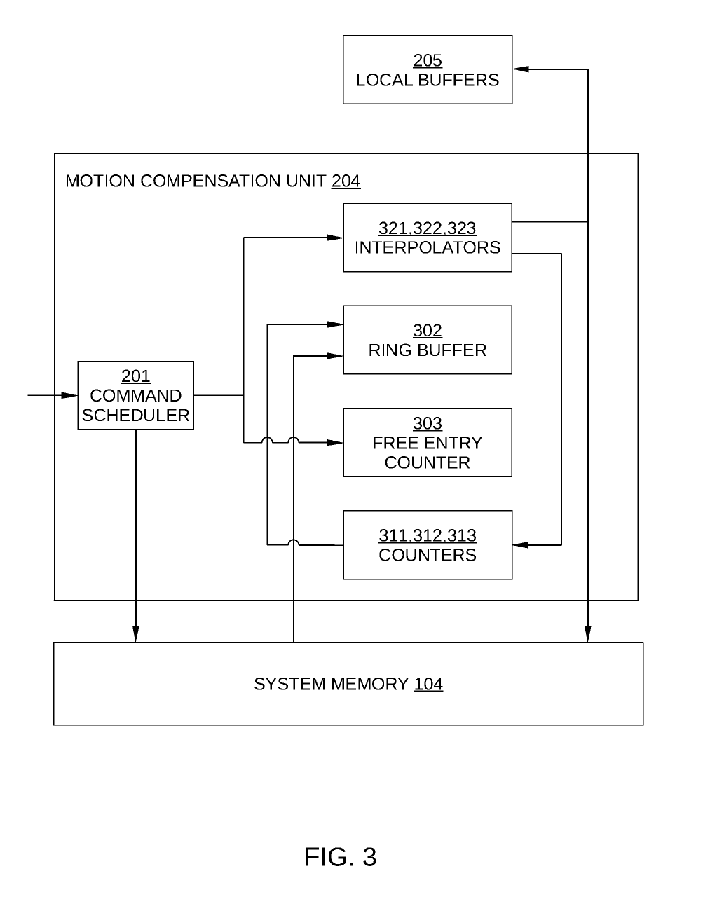

FIG. 2 is a block diagram illustrating video decoding unit 120 of FIG. 1, according to an embodiment of the present invention. As shown, video decoding unit 120 may include a bitstream parser 201, a motion vector calculator 202, an inverse transformer 203, a motion compensation unit 204, local buffers 205, and a post processing module 206. In operation, video decoding unit 120 receives commands from CPU 102 via communication path 113 and data from system memory 104, and routes data and commands as shown. Motion compensation module 204 performs an interpolation process on data blocks that are determined based on operations carried out by motion vector calculator 202 and inverse transformer 203. In some embodiments, output from motion compensation module 204 is stored in system memory 104. Alternatively, output from motion compensation module 204 may be stored in one or more local buffers 205. The organization and operation of one embodiment of motion compensation module 204 is describe below in conjunction with FIG. 3.

FIG. 3 is a block diagram illustrating motion compensation module 204 of FIG. 2, according to an embodiment of the present invention. As shown, motion compensation module 204 may include a command scheduler 301, a ring buffer 302, a free entry counter 303, counters 311-313, and interpolators 321-323, arranged as shown. Motion compensation module 204 receives commands and data from upstream units of video decoding unit 120, including motion vector calculator 202 and inverse transformer 203, and outputs data blocks that have undergone an interpolation process to system memory 104 and/or local buffers 205.

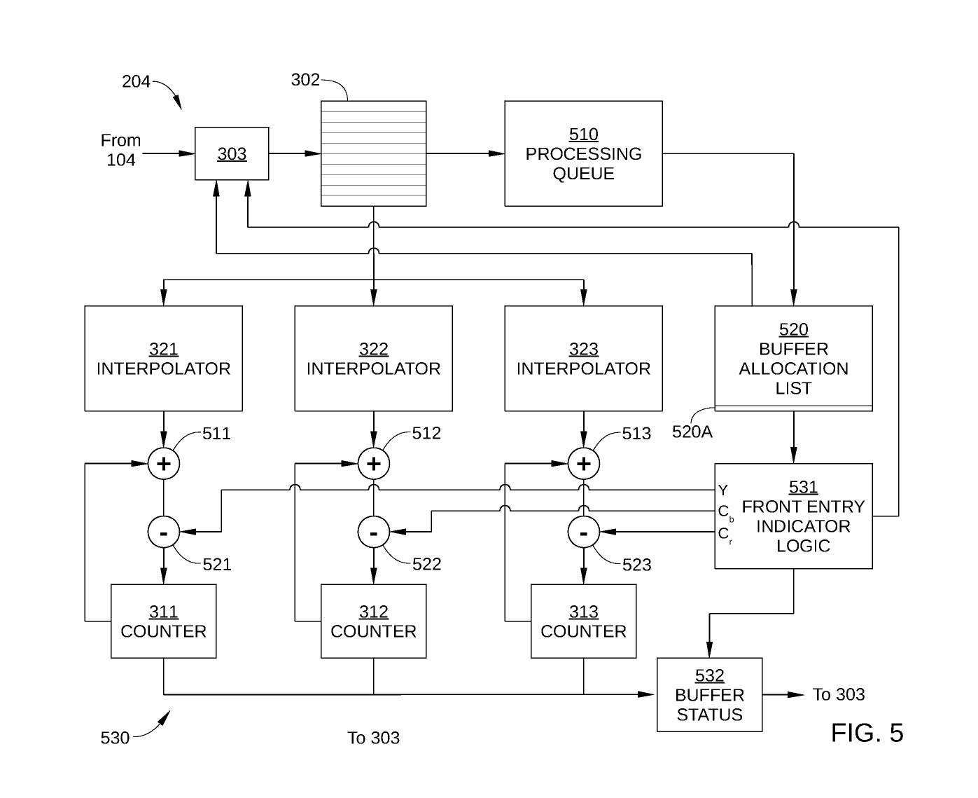

Command scheduler 301, in conjunction with other logic devices in motion compensation module 204, is configured to control the operations of motion compensation module 204 to implement interpolation of data blocks as well as a reordering scheme that prevents out-of-order completion of such interpolation from affecting operation of ring buffer 302. Examples of such an interpolation process and reordering scheme are described below in conjunction with FIG. 5. Typically, command scheduler 301 is a hardware entity disposed proximate the other elements of motion compensation module 204.

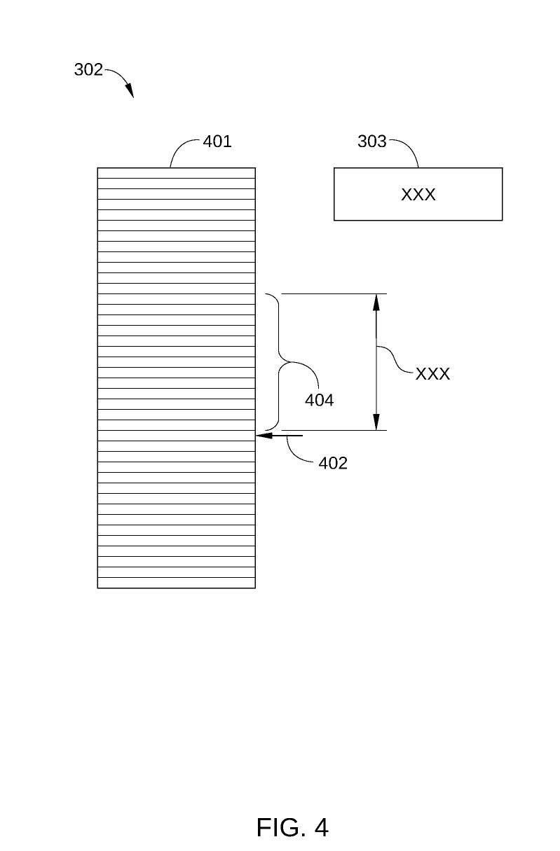

Ring buffer 302 stores data blocks on which interpolation is to be performed as part of a video decoding process. Ring buffer 302 is configured as a first-in-first-out (FIFO) data structure with a fixed storage size, and stores data blocks for interpolators 321-323 (or other processing engines) that perform interpolation in parallel with each other. One embodiment of ring buffer 302 is illustrated in FIG. 4.

FIG. 4 is a schematic diagram illustrating ring buffer 302 of FIG. 3, according to an embodiment of the present invention. As shown, ring buffer 302 includes a storage volume 401, a start pointer 402, and free entry counter 303. Storage volume 401 is generally configured to have a fixed capacity, for example 256 bytes, and is sized to store a plurality of data blocks that are designated for interpolation and which may be non-uniform in size. For example, as part of an interpolation process, a data block stored in storage volume 401 may be one of luma data, chroma red data, or a chroma blue data, where luma data blocks are generally larger than the chroma data blocks. Start pointer 402 includes a value indicating an address in storage volume 401 at which valid entries begin, and free entry counter 303 includes a value indicating how many bytes of storage volume 401 are currently available for storing additional data blocks.

Taken together, start pointer 402 and free entry counter 303 define an available region 404 of storage volume 401 that can be used to store data blocks for interpolation by interpolators 221-223. For example, when start pointer 402 has a value of 32 bytes and free entry counter 303 has a value of 16 bytes, available region 404 corresponds to bytes 16 to 31 of storage volume 401. When the oldest entry in ring buffer 302 is released, as described below in conjunction with FIG. 5, the respective values of start pointer 402 and free entry counter 303 are updated accordingly. In this way, start pointer 402 and free entry counter 303 manage what portion of storage volume 401 is available for storing additional data blocks. While the embodiment of ring buffer 302 illustrated in FIG. 4 includes start pointer 302 and free entry counter 303, other configurations of ring buffer 302 may be used in other embodiments.

Because ring buffer 302 operates as a FIFO data structure, the oldest entry in ring buffer 302 is processed first. Once this processing is completed, the storage space associated with the processed entry is released and made available for storing some or all of a new entry in ring buffer 302. Thus, data blocks can be designated for interpolation in a certain order, stored in ring buffer 302 in that order, and then processed by a suitable one of interpolators 321, 322, or 323. However, interpolators 321-323 may complete processing of data in out of order, since different interpolator operations take longer to complete than others. For example, decoding a luma data block generally takes longer than decoding a chroma data block. Such out-of-order processing is problematic when sharing ring buffer 302, because deallocation of storage volume 401 must be performed in the correct order to avoid over-writing portions of storage volume 401 that contain valid data. An example reordering scheme for deallocating storage volume 401 safely is described below in conjunction with FIG. 5.

Interpolators 321-323 are processing engines included in motion compensation unit 204 and are configured to perform one or more operations associated with video decoding, such as decoding luma data blocks, chroma red data blocks, and/or chroma blue data blocks. In some embodiments, interpolators 321-323 are general purpose interpolators that are substantially homogeneous in configuration, and can decode any data block type. In other embodiments, interpolators 321-323 are heterogeneous in configuration, and are each configured to decode a specific data block type, e.g., luma data blocks vs. chroma data blocks.

Each of counters 311-313 is associated with and tracks the availability of one of interpolators 321-323. Together, counters 311-313 are configured to manage deallocation of a portion of storage ring buffer 302 according to an example deallocation scheme described below in conjunction with FIG. 5.

FIG. 5 is a block diagram illustrating elements of motion compensation unit 204 of FIG. 2 configured to implement a reordering scheme for the release of data stored in ring buffer 302, according to an embodiment of the present invention. As noted previously, motion compensation module 204 may include ring buffer 302, free entry counter 303, counters 311-313, and interpolators 321-323. In the embodiment illustrated in FIG. 5, motion compensation unit 204 also includes a processing queue 510, a buffer allocation list 520, and reordering logic 530.

Processing queue 510 is configured to store meta data of data blocks that have been stored in ring buffer 302 for processing by interpolators 321-323. For example, for each data block stored in ring buffer 302, processing queue 510 may be configured to store attributes such as data block address, size (e.g., in bytes), width, height, and data block type. In the context of video decoding, such data block types may include luma, chroma red, and chroma blue. Thus, for each data block stored in ring buffer 302, a corresponding portion of processing queue 510 is populated with meta data associated with the data block. In some embodiments, processing queue 510 is a FIFO data structure configured to be populated with the above-described meta data.

Buffer allocation list 520 is a data structure configured to track the order, size, and type of each data block stored in ring buffer 302. In some embodiments, instead of or in addition to storing data block type (e.g., luma, chroma, etc.), buffer allocation list 520 stores an entry indicating which interpolator is designated to decode the data block. In some embodiments, buffer allocation list 520 is a FIFO data structure in which the front entry 520A (i.e., the oldest entry) is cleared when the corresponding oldest entry in ring buffer 302 is released for storing new data. A process by which a determination is made for when the oldest entry in ring buffer 302 is cleared is performed by deallocation logic 530 and is described below.

Deallocation logic 530 is depicted schematically in FIG. 5, and includes front entry indicator logic 531, buffer status logic 532, counters 311-313, summing functions 511-513, and difference functions 521-523. According to some embodiments, deallocation logic 530 is configured to implement a reordering scheme for deallocation of memory in ring buffer 302 to account for out-of-order completion of data processing by interpolators 311-313. Specifically, deallocation logic 530 is configured to ensure that each portion of ring buffer 302 is released for storing new data (i.e., deallocated) in the same order in which each portion of ring buffer 302 is allocated to store data blocks.

Front entry indicator logic 531 is configured to indicate to each of counters 311-313 a status of the current front entry 520A of buffer allocation list 520. Specifically, front entry indicator logic 531 is configured to indicate to each of counters 311-313 if front entry 520A of buffer allocation list 520 corresponds to a data block that is designated to be processed by that particular interpolator. In the embodiment illustrated in FIG. 5, front entry indicator logic 531 is configured to output a “1” value to a particular counter when front entry 520A is designated to be processed by that interpolator, and output a “0” value to that counter when front entry 520A is designated to be processed by a different interpolator. Alternatively, when interpolators 321-323 have heterogeneous configurations, front entry indicator logic 531 may be configured to output a “1” value to the counter associated with a particular type of interpolator (e.g., the chroma-red compatible interpolator) when front entry 520A is of a data type compatible with that interpolator type. In the embodiment illustrated in FIG. 5, front entry indicator logic 531 is configured to indicate whether a luma data block (Y), a chroma red data block (Cᵣ), or a chroma blue data block (C_{b}) is currently in front entry 520A.

Counters 311-313 are coupled to interpolators 321-323, respectively, and are configured to increment or decrement based on input from the interpolator coupled thereto and from front entry indicator logic 531. For example, in the case of counter 311, when interpolator 321 completes an operation on a particular data block, counter 311 increments by a value of 1. Thus, when interpolator 321 completes a decoding operation on a data block, counter 311 has a value of 1. In addition, when the front entry 520A of buffer allocation list 520 corresponds to a data block that was designated to be processed by interpolator 321, front entry indicator logic 531 outputs a “1” value to difference function 511 and counter 311 decrements by a value of 1. Thus counter 311 is returned from a value of 1 (after completing processing of a data block) to 0, meaning interpolator 321 has no pending entries to be deallocated. In this way, counter 311 is reset after interpolator 321 has processed a data block and a portion of ring buffer 302 corresponding to the processed data block has been deallocated.

Buffer status logic 532 compares the value of each of counters 311-313 to zero, and under certain condition outputs a signal to fee entry counter 303 indicating that a portion of ring buffer 302 corresponding to a data block processed by an interpolator can be deallocated. Specifically, when a counter (e.g., counter 311) has a value of 1, meaning that the corresponding interpolator (e.g., interpolator 321) has completed processing of a data block, and front entry indicator logic 531 indicates that front entry 520A corresponds to a data block that was designated to be processed by the interpolator, buffer status logic 532 sends the signal to free entry counter 303. When a counter has a value of 1 and front entry indicator logic 531 indicates that front entry 520A does not correspond the interpolator, buffer status logic 532 does not send the signal to free entry counter 303.

In operation, motion compensation module 204 receives data blocks from system memory 104 and stores these data blocks in ring buffer 302. Motion compensation module 204 then populates processing queue 510 with meta data corresponding to attributes of the data blocks stored in ring buffer 302 (e.g., data block address, size, width, height, data block type, etc.). According to processing queue 510, data blocks from ring buffer 302 are then sent to a suitable one of interpolators 321-323, and buffer allocation list 520 is populated with an entry for each data block stored in ring buffer 302, where the entry includes the size and type of the data block. When a particular interpolator completes processing of a data block, an output of value 1 is output to the summing function for that interpolator and the counter associated with that interpolator is incremented by a value of 1. In addition, the processed data block is sent to system memory 104 or optionally to a local buffer, such as one of buffers 205 in FIG. 2, for subsequent use by computer system 100.

When a suitable data block is indicated to be in the current front entry 520A, motion compensation module 204 is configured to release a portion of ring buffer 302 that corresponds in size to the data block just processed by the interpolator. For example, when interpolators 321-323 have heterogeneous configurations and interpolator 321 is configured to process luma data block types, front entry indicator logic 531 sends an output of value 1 to the difference function for each of interpolators 321-323 that are configured to process luma data block types (in FIG. 5, this is just difference function 521. In addition, buffer status logic 532 signals to free entry counter 303 to update free space in ring buffer 302 by the size of the luma data block just processed by interpolator 311 (i.e. the size of front entry 520A), and signals to start pointer 402 (shown in FIG. 4) to relocate (i.e., change value) accordingly. Buffer status logic 532 also signals to to buffer allocation list 520 to release front entry 520A so that the next entry in buffer allocation list 520 is now front entry 520A. Because the size of front entry 520A is stored in buffer allocation list 520, in some embodiments, buffer allocation list 520 notifies free entry counter 303 how much space free entry counter is to update free space in ring buffer 302. Because front entry indicator logic 531 sends an output of value 1 to, for example, difference function 511, counter 311 is decremented from a value of 1 to 0.

Front entry indicator 531 acts to deallocate the buffers in ring buffer 302 in the same order these buffers were allocated. For example, if the front entry is luma, and the second entry is chroma, and the chroma counter is 1, but the luma counter is 0, nothing will be deallocated. Once the luma interpolator is done and increments the luma counter, then the first entry (luma) will be deallocated from the buffer, and immediately after that the second entry will be deallocated (since chroma counter=1 and the next entry is chroma). This functionality prevents out-of-order deallocation of a portion of ring buffer 302, which can result in over-writing valid data in ring buffer 302. Since the oldest entry in ring buffer 302 is only released when a data block corresponding to that entry has been decoded by an interpolator (as tracked by buffer allocation list 520), the completion of processing of a data block that is not the oldest entry in ring buffer 302 does not result in a portion of ring buffer 302 being released. In this way, out-of-order completion of processing by one or more of interpolators 321-323 does not result in out-of-order deallocation of portions of ring buffer 302.

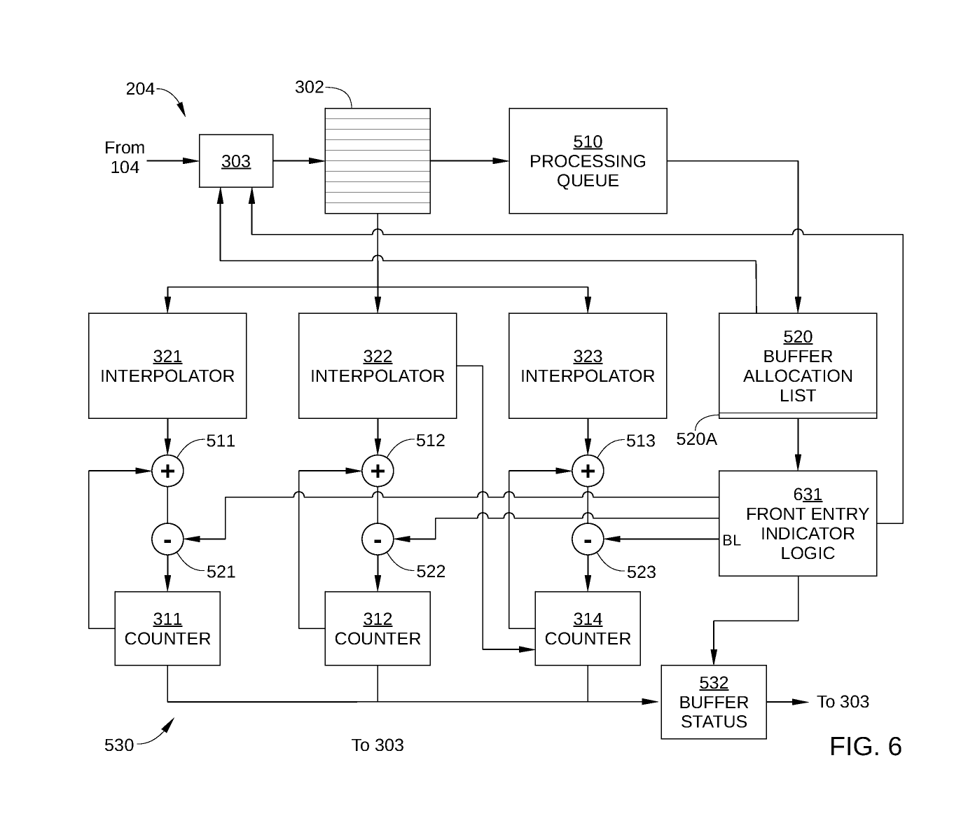

In some embodiments, a data block type may be processed by a combination of interpolators, and a dedicated counter is used to track whether a data block has been processed by two interpolators before the corresponding entry in buffer allocation list 520 can be released. For example, in video decoding, different interpolating methods (bilinear, bicubic, etc.) may be used. Depending on the interpolation method, the data block may be processed by two interpolators. One such embodiment is described below in conjunction with FIG. 6.

FIG. 6 is a block diagram illustrating elements of motion compensation unit 204 of FIG. 2 in which a bilinear data block may be processed, according to an embodiment of the present invention. As shown, a dedicated bilinear done counter 314 is coupled to two interpolators (e.g., interpolators 322 and 323) and is used to track completion of interpolation of a bilinear data block by these two interpolators. In addition, a front entry indicator logic 631 tracks what data block type is currently in front entry 520A of buffer allocation list 520. As with other data block types, buffer status logic 532 does not indicate that a portion of ring buffer 302 can be released unless front entry 520A corresponds to the data block just processed by these interpolators. Once front entry 520A corresponds to a data block just processed by interpolators 322 and 323, as indicated by front entry indicator logic 631, a portion of ring buffer 302 is released for storing new data that is equal in size to the size of the bilinear data block.

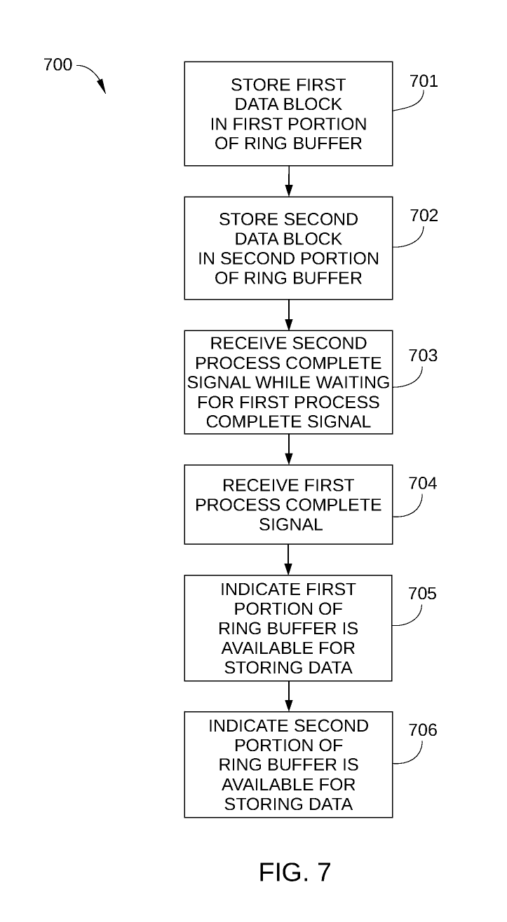

FIG. 7 sets forth a flowchart of method steps for managing data processed by multiple processing engines, according to one embodiment of the present invention. Although the method steps are described with respect to the systems of FIGS. 1-6, persons skilled in the art will understand that any system configured to perform the method steps, in any order, falls within the scope of the present invention.

As shown, a method 700 begins at step 701, where command scheduler 301 of video motion compensation unit 204 or other suitable control circuit or system stores a first data block associated with a first processing engine in a first portion of a ring buffer memory. For example, a module of video decoding unit 120 may determine that a particular data block should undergo interpolation, so this data block is retrieved from system memory 104 and loaded into the first available storage volume in ring buffer 302 as the last entry in ring buffer 302. In some embodiments, a specific interpolator may be designated for processing the data block, and in other embodiments, any interpolator of a specific type may be designated for processing the data block. For example, when the data block is a chroma data block, any of the interpolators in video compensation unit 204 that are compatible with processing a chroma data block may be designated for processing the data block. In some embodiments, command scheduler 301 also updates an allocation list (e.g., buffer allocation list 520) in step 701 that is associated with ring buffer 302. This allocation list is updated with an entry that includes a size of the first data block (e.g., in bytes) and a data type of the first data block (e.g., luma, chroma, bilinear, etc.).

In step 702, subsequent to storing the first data block, command scheduler 301 or other suitable control circuit or system stores a second data block associated with a second processing engine in a second portion of the ring buffer memory. Similar to step 701, a module of video decoding unit 120 may determine that a particular data block should undergo interpolation. This data block is retrieved from system memory 104 and loaded into an available storage volume in ring buffer 302 that is later in the processing queue than the data block stored in ring buffer 302 in step 701.

In step 703, command scheduler 301 or other suitable control circuit or system receives a second process complete signal from the second processing engine while waiting for a first process complete signal from the first processing engine. Thus, the interpolator that processes the data block stored in step 702 completes the processing of this data block before the interpolator designated to process the data block stored in step 701 completes the processing of that data block. Because processing of the second data block begins after the processing of the first data block, this situation occurs when the processing of the second data block is completed more quickly than the processing of the first data block. It is noted that command scheduler 301 does not indicate that a portion of ring buffer 302 is now released and available for storing data. Instead, command scheduler 301 waits to receive a first process complete signal from the first processing engine.

In step 704, command scheduler 301 or other suitable control circuit or system receives the first process complete signal from the first processing engine once the first processing engine completes processing of the first data block. In some embodiments, the first process complete signal is received by command scheduler 301 from a processing engine when two criteria are met: 1) the processing engine completes processing the first data block, and 2) the front entry of a buffer allocation list associated with ring buffer 302 (e.g., front entry 520A of buffer allocation list 520) corresponds to the first data block that was just processed by that particular processing engine.

In step 705, upon receiving the first process complete signal, command scheduler 301 or other suitable control circuit or system indicates that the first portion of the buffer memory is available for storing data other than the first data block. In some embodiments, command scheduler 301 indicates the first portion of ring buffer 302 is available for data storage by updating a free entry counter associated with ring buffer 302 (e.g., free entry counter 303) by a value equal to the size of the first data block that was just processed by the first processing engine. In such embodiments, as part of indicating that the first portion of the ring buffer is available for data storage, command scheduler 301 may also change a value of a start pointer associated with ring buffer 302 (e.g., start pointer 402) by a value that is equal to the size of the first data block. It is noted that after step 705, command scheduler 301 can safely store some or all of another data block in the portion of ring buffer 302 indicated in step 705 to be available for storing data other than the first data block.

In step 706, after indicating in step 705 that the first portion of ring buffer 302 is available for storing data other than the first data block, command scheduler 301 indicates that the second portion of ring buffer 302 is available for data storage, since the second process complete signal from the second processing engine has already been received.

As persons skilled in the art will appreciate, the approach of method 700, as described herein, may be applied to any technically feasible computing device configured to process data with multiple processing engines that share a common ring buffer. Furthermore, embodiments described herein are applicable to any set of multiple processing engines or processors that processes and stores data in buffer memory, such as out-of-order CPU execution units and audio processing engines.

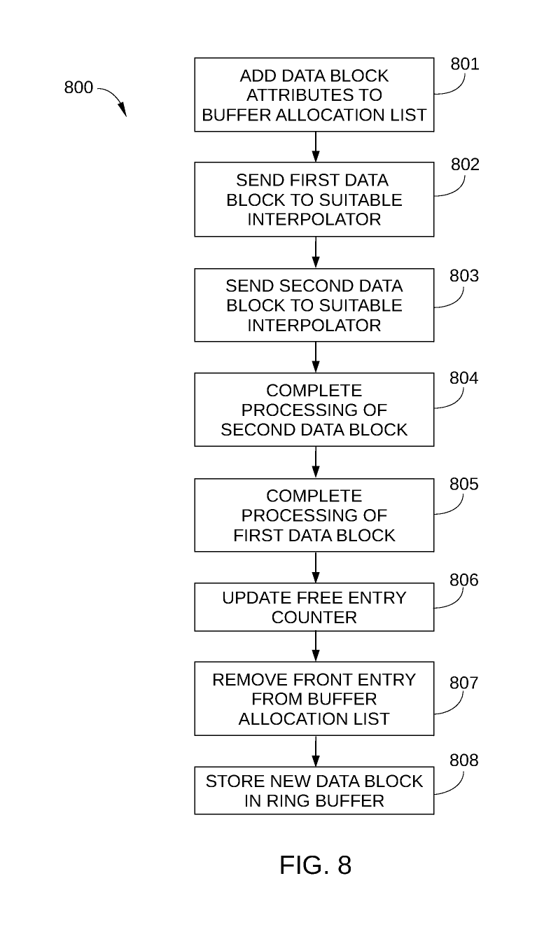

FIG. 8 sets forth a flowchart of method steps for a process flow of data processed by multiple processing engines, according to one embodiment of the present invention. Although the method steps are described with respect to the systems of FIGS. 1-6, persons skilled in the art will understand that any system configured to perform the method steps, in any order, falls within the scope of the present invention.

Prior to the method, motion compensation module 204 receives a plurality of data blocks from system memory 104 that are to undergo an interpolation process and allocates these blocks, in the order received, to ring buffer 302. Such data blocks may be received until ring buffer 302 is full, i.e., until ring buffer no longer has sufficient available storage space to receive another data block. Available storage space in ring buffer 302 is indicated by free entry counter 303, which is updated as described below.

As shown, a method 800 begins at step 801, where attributes of the data blocks stored in ring buffer 302 are added to a processing queue for interpolators 321-323, and certain of these attributes are also added to buffer allocation list 520. Specifically, the size and type of each data block stored in ring buffer 302 is stored in buffer allocation list 520 in the same order in which the corresponding data blocks are stored in ring buffer 302.

At step 802, the first available data block in ring buffer 302 is sent to an interpolator that is suitable for processing the data block. For example, interpolator 321 may be configured to process luma data block types, and the first available data block in ring buffer 302 is a luma data block. In some embodiments, the data block in the front entry of ring buffer 302 is indicated by start pointer 402.

At step 803, while the first available data block in ring buffer 302 is being processed by an interpolator, e.g., interpolator 321, the next available data block in ring buffer 302 is sent to a suitable processor. For example, interpolator 322 may be configured to process chroma data block types, and the next available data block in ring buffer 302 may be a choma data block.

In step 804, interpolator 322 completes processing of the chroma data block. Because chroma data blocks can generally be interpolated more quickly than luma data blocks, interpolator 322 completes this processing prior to interpolator 321 completing the interpolation of the luma data block received in step 802. In addition, counter 312 is incremented by a value of 1 in response to interpolator 322 completing the processing of the chroma data block. However, it is noted that because front entry 520A of buffer allocation list 520 is a luma block (corresponding to the data block currently being processed by interpolator 321), front entry indicator logic 531 outputs a value of 0 to difference function 512. Thus, because counter 311 does not equal 0, interpolator 321 is not considered available for processing another data block, and a portion of ring buffer 302 is not released at this time.

In step 805, interpolator 321 completes processing of the luma data block. Accordingly, counter 311 is incremented by a value of 1. In addition, because front entry 520A is a luma block, front entry indicator logic 531 outputs a value of 1 to difference function 511. Consequently, counter 311 is decremented by a value of 1, back down to zero.

In step 806, free entry counter 303 is updated by a value equal to the size of front entry 520A, which corresponds to the data block interpolator 321 has just completed processing. In this way, despite out-of-order completion of data blocks stored in ring buffer 302, a portion of ring buffer 302 that corresponds in size to the data block just processed by interpolator 321 is released and can be safely used to store a new data block without overwriting needed data.

In step 807, front entry 520A is removed from buffer allocation list 520 and the oldest remaining entry in buffer allocation list 520 then occupies front entry 520A. In this example, because the next data block stored in ring buffer 302 (after the luma block that was processed by interpolator 321 in step 807) is a chroma block, the oldest remaining entry in buffer allocation list 520 corresponds to this chroma data block.

In step 808, one or more new data blocks are stored in the available portion of ring buffer 302, and buffer allocation list 520 is updated with the size and type of these new data blocks stored in ring buffer 302.

As persons skilled in the art will appreciate, the approach of method 800, as described herein, may be applied to any technically feasible computing device configured to process data with multiple processing engines that share a common ring buffer. Furthermore, embodiments described herein are applicable to any set of multiple processing engines that processes and stores data in buffer memory.

In sum, embodiments of the invention set forth systems and methods for managing data processed by multiple processing engines and stored in a common ring buffer memory. According to some embodiments, by reordering deallocation of ring buffer resources when out-of-order processing of data stored in the ring buffer occurs, out-of-order deallocation of memory locations in the ring buffer is avoided. This enables the use of a ring buffer with multiple processing engines, which advantageously reduces processing latency and interpolator idle time. Because the ring buffer always has a front entry available for processing, there is no latency associated with fetching data from physical memory or with retaining processed data blocks in a buffer until all data blocks in the buffer are process. In addition, interpolators are not idle while waiting for other interpolators to complete processing of data blocks.

One embodiment of the invention may be implemented as a program product for use with a computer system. The program(s) of the program product define functions of the embodiments (including the methods described herein) and can be contained on a variety of computer-readable storage media. Illustrative computer-readable storage media include, but are not limited to: (i) non-writable storage media (e.g., read-only memory devices within a computer such as compact disc read only memory (CD-ROM) disks readable by a CD-ROM drive, flash memory, read only memory (ROM) chips or any type of solid-state non-volatile semiconductor memory) on which information is permanently stored; and (ii) writable storage media (e.g., floppy disks within a diskette drive or hard-disk drive or any type of solid-state random-access semiconductor memory) on which alterable information is stored.

While the foregoing is directed to embodiments of the present invention, other and further embodiments of the invention may be devised without departing from the basic scope thereof, and the scope thereof is determined by the claims that follow.

The claimed invention is:

1. A computer-implemented method for managing data processed by multiple processing engines, the method comprising:
storing a first data block associated with a first processing engine in a first portion of a ring buffer memory;
subsequent to storing the first data block, storing a second data block associated with a second processing engine in a second portion of the ring buffer memory;
receiving a second process complete signal from the second processing engine while waiting for a first process complete signal from the first processing engine;
receiving the first process complete signal from the first processing engine once the first processing engine completes processing of the first data block; and
upon receiving the first process complete signal, indicating that the first portion of the ring buffer memory is available for storing data other than the first data block.

2. The method of claim 1, wherein the first data block is of a first data type and the second data block is of a second data type.

3. The method of claim 2, wherein each of the first data type and the second data type comprises a different data type associated with a video decoding process.

4. The method of claim 3, wherein each of the first data type and the second data type comprises a luma, a chroma red or a chroma blue data type.

5. The method of claim 1, further comprising, subsequent to indicating that the first portion is available for storing data, indicating that the second portion is available for storing data other than the second data block.

6. The method of claim 1, further comprising, subsequent to indicating that the first portion is available for storing data, storing a third data block in the first portion of the ring buffer memory.

7. The method of claim 1, wherein the first data block has a different size than the second data block.

8. The method of claim 1, further comprising updating an allocation list associated with the ring buffer with an entry that includes a size of the first data block and a data type associated with the first data block.

9. The method of claim 8, wherein the first portion of the ring buffer is the same size as the first data block.

10. The method of claim 9, wherein indicating the first portion of the ring buffer is available for storing data comprises incrementing a free entry counter associated with the ring buffer by an amount equal to the size of the first data block.

11. The method of claim 9, wherein indicating the first portion of the ring buffer is available for storing data comprises changing a value of a start pointer associated with the ring buffer by an amount equal to the size of the first data block.

12. A subsystem configured to manage data processed by multiple processing engines, the subsystem comprising:
a ring buffer memory; and
a controller configured to:
store a first data block associated with a first processing engine in a first portion of the ring buffer memory;
subsequent to storing the first data block, store a second data block associated with a second processing engine in a second portion of the ring buffer memory;
receive a second process complete signal from the second processing engine while waiting for a first process complete signal from the first processing engine;
receive the first process complete signal from the first processing engine once the first processing engine completes processing of the first data block; and
upon receiving the first process complete signal, indicate that the first portion of the buffer memory is available for storing data other than the first data block.

13. The subsystem of claim 12, wherein each of the first processing engine and the second processing engine each comprises a video interpolator.

14. The subsystem of claim 13, wherein the first processing engine comprises an interpolator configured to process luma data blocks as part of a video decoding process and the second processing engine comprises an interpolator configured to process chroma data blocks as part of the video decoding process.

15. The subsystem of claim 12, wherein the first data block is of a first data type and the second data block is of a second data type.

16. The subsystem of claim 12, wherein each of the first data type and the second data type comprises a different data type associated with a video decoding process.

17. The subsystem of claim 12, further comprising control logic that is coupled to the first processing engine and the second processing engine and is configured to generate the first process complete signal and the second process complete signal.

18. The subsystem of claim 12, further comprising a data structure configured to track the order, size, and data type of data blocks stored in the ring buffer memory.

19. The subsystem of claim 18, further comprising control logic that is coupled to the first processing engine, the second processing engine, and the data structure, and is configured to generate the first process complete signal and the second process complete signal.

20. A computing device comprising:
a memory; and
a subsystem coupled to the memory and configured to manage data processed by multiple processing engines, the subsystem including
a ring buffer memory; and
a controller configured to:
store a first data block associated with a first processing engine in a first portion of the ring buffer memory;
subsequent to storing the first data block, store a second data block associated with a second processing engine in a second portion of the ring buffer memory;
receive a second process complete signal from the second processing engine while waiting for a first process complete signal from the first processing engine;
receive the first process complete signal from the first processing engine once the first processing engine completes processing of the first data block; and
upon receiving the first process complete signal, indicate that the first portion of the buffer memory is available for storing data other than the first data block.
